(19) United States
(12) Patent Application Publication
(10) Pub. No.: US 2024/0099011 A1
(43) Pub. Date: Mar. 21, 2024

(54) VERTICAL NAND WITH BACKSIDE STACKING

(71) Applicant: International Business Machines Corporation, Armonk, NY (US)

(72) Inventors: Min Gyu Sung, Latham, NY (US); Soon-Cheon Seo, Glenmont, NY (US); Chen Zhang, Guilderland, NY (US); Ruilong Xie, Niskayuna, NY (US); Heng Wu, Santa Clara, CA (US); Julien Frougier, Albany, NY (US)

(21) Appl. No.: 17/932,347

(22) Filed: Sep. 15, 2022

(51) Int. Cl. H01L 27/11573; H01L 27/11529

(52) U.S. Cl. CPC H01L 27/11573; H01L 27/11529

(57) ABSTRACT

The present invention provides semiconductor structures. The semiconductor structures may include a peripheral complimentary metal-oxide semiconductor (CMOS) substrate, a first vertical NAND cell on a first side of the CMOS substrate, and a second vertical NAND cell on a second side of the CMOS substrate opposite the first side.

### FIELD OF THE INVENTION

The present invention relates to memory devices, and more particularly, to vertical NAND cells on a first and a second side of a peripheral complimentary metal-oxide semiconductor (CMOS) substrate.

### BACKGROUND OF THE INVENTION

NAND is non-volatile flash memory storage that does not need power to retain data. NAND storage appears in a wide range of products, from small consumer devices to high-capacity SSDs in flash-based enterprise data centers. NAND cell arrays store 1, 2, 3, or 4 bits of data. When the NAND SSD or card is detached from a power source, metal-oxide semiconductors called floating-gate transistors (FGT) provide electrical charges to the memory cells, and data remains intact.

Stacked or three-dimensional (3D) NAND, also called V NAND, is an integrated circuit design that uses stacking of memory cells within a single chip. Such an architecture may include the FGTs stacked vertically in layers. 3D NAND technology can produce devices that operate faster, hold more information more densely and efficiently, and use less energy. A 3D NAND architecture can advantageously reduce the footprint of the device, while increasing efficiency and reducing costs when compared to its planar or two-dimensional (2D) counterpart.

The fabrication process for 3D NAND adds multiple layers of memory cells on top of each other, along with interconnections between the layers. A typical 3D NAND flash chip can easily include 32 to 48 individual layers, with 64, 96, or 128-layer devices also conceived. The increase of layers, however, makes it more difficult to manufacturer.

### SUMMARY

The present invention provides semiconductor structures. The semiconductor structures may include a peripheral complimentary metal-oxide semiconductor (CMOS) substrate, a first vertical NAND cell on a first side of the CMOS substrate, and a second vertical NAND cell on a second side of the CMOS substrate opposite the first side. The semiconductor structures may further include a first CMOS device connected to the first vertical NAND cell and a second CMOS device connected to the second vertical NAND cell.

In another aspect of the invention, a method may be used to form a semiconductor structure. The method may include forming a peripheral complimentary metal-oxide semiconductor (CMOS) substrate, forming a first vertical NAND cell on a first side of the CMOS substrate, flipping the CMOS, and forming a second vertical NAND cell on a second side of the CMOS substrate opposite the first side.

In yet another aspect of the invention, a semiconductor structure is provided. The semiconductor structure may include a first vertical NAND cell oriented in a first direction relative to a peripheral complimentary metal-oxide semiconductor (CMOS) substrate and a second vertical NAND cell oriented in a second direction opposite the first direction relative to the CMOS substrate.

A more complete understanding of the present invention, as well as further features and advantages of the present invention, will be obtained by reference to the following detailed description and drawings.

### BRIEF DESCRIPTION OF THE DRAWINGS

FIG. 1 is a cross-sectional side view of a semiconductor structure at a fabrication stage, in accordance with one embodiment of the present invention.

FIG. 2 is a cross-sectional side view of the semiconductor structure of FIG. 1 at a fabrication stage, in accordance with one embodiment of the present invention.

FIG. 3 is a cross-sectional side view of the semiconductor structure of FIG. 1 at a fabrication stage, in accordance with one embodiment of the present invention.

### DETAILED DESCRIPTION

Provided herein are designs for increasing device density for NAND devices. In particular, three-dimensional (3D) stack NAND device designs that include a vertical NAND cells on two sides of a peripheral complimentary metal-oxide semiconductor (CMOS) substrate. A NAND device is a semiconductor logic device with transistors that collectively serve as a logical gate for performing logic operations on logical values. In the case of a NAND gate, the NAND logic operator produces a FALSE value only if both values of its two inputs are TRUE. The individual memory cells of the vertical NAND cell are controlled by CMOS transistors in the CMOS substrate. Specifically, the CMOS transistors operate to control bitlines and wordlines that provide an address for each memory cell. Distances between the bitlines/wordlines and the controlling CMOS transistors can affect the performance of the NAND device. Therefore, the embodiments disclosed herein minimize the distance between the CMOS substrate and the bitline by fabricating the NAND cells on both sides of the CMOS substrate.

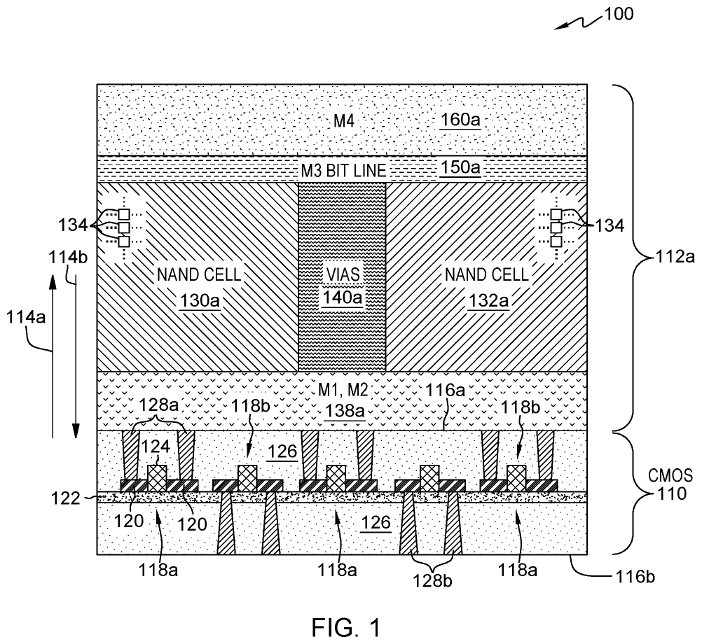

An exemplary methodology for forming a semiconductor structure 100 (e.g., a 3D stack NAND device) in accordance with the present techniques is now described with reference to FIGS. 1-3. As shown in FIG. 1, the semiconductor structure 100 includes a CMOS substrate 110 with a first half 112a formed in a first direction 114a on a first side 116a of the CMOS substrate 110.

According to an exemplary embodiment, the CMOS substrate 110 is fabricated from a bulk semiconductor wafer, such as a bulk silicon (Si), bulk germanium (Ge), bulk silicon germanium (SiGe) and/or bulk III-V semiconductor wafer. Alternatively, the CMOS substrate 110 can be a semiconductor-on-insulator (SOI) wafer. A SOI wafer includes a SOI layer separated from an underlying substrate by a buried insulator. When the buried insulator is an oxide it is referred to herein as a buried oxide or BOX. The SOI layer can include any suitable semiconductor, such as Si, Ge, SiGe, and/or a III-V semiconductor.

As shown in FIG. 1, multiple field effect transistors (FETs) 118a, b are formed in the CMOS substrate 110. Generally, the FETs 118a, b are standard transistors, with each transistor including source/drains 120 interconnected by a channel 122. A gate 124 is disposed over the channel 122 that regulates current flow through the channel. Source/drains 120 are doped with an n-type or p-type dopant depending on whether an n-channel FET (NFET) or a p-channel FET (PFET) is being formed. Suitable n-type dopants include, but are not limited to, phosphorous (P) and/or arsenic (As), and suitable p-type dopants include, but are not limited to, boron (B).

While not explicitly shown in the figures, it would be apparent to one skilled in the art that the gate can include a stack of materials. For instance, according to an exemplary embodiment, gate includes a gate dielectric (not shown) disposed on the channel and a gate conductor(s) (not shown) disposed on the gate dielectric. The source/drains 120 may also have configurations other than the orientations shown in the figures here.

The FETs 118a, b may be buried in an interlayer dielectric (ILD) 126 that insulates one FET 118a from another FET 118b. Suitable materials for ILD include, but are not limited to, oxide materials such as silicon oxide (SiOx) and/or organosilicate glass (SiCOH) and/or ultralow-K interlayer dielectric (ULK-ILD) materials, e.g., having a dielectric constant κ of less than 2.7. By comparison, silicon dioxide (SiO₂) has a dielectric constant κ value of 3.9. Suitable ultralow-κ dielectric materials include, but are not limited to, porous organosilicate glass (pSiCOH). The FETs 118a, b include contacts 128a, b that have at least two orientations for fabrication. First contacts 128a may be fabricated in the first direction 114a such that the first contacts 128a for the first FETs 118a are exposed on the first side 116a of the CMOS substrate 110. Second contacts 128b for the second FETs 118b may be fabricated in a second direction 114b such that the second contacts 128b are exposed on a second side 116b of the CMOS substrate 110.

Source and drain contacts are connected to metal pads in first metal interconnect layers 138a that interconnect the sources, drains, and/or gate line from the FETs 118a, b. The first metal interconnect layers 138a include metal lines, trenches, and/or vias that interconnect to enable control of the first FETs 118a in the CMOS substrate 110. According to an exemplary embodiment, the first metal interconnect layers 138a are formed from metal or other conductive material insulated by dielectric or other insulative material. The first metal interconnect layers 138a are connected only to the first FETs 118a on the first side 116a of the CMOS substrate 110. In the illustrated embodiment, the first metal interconnect layers 138a include two metal interconnect layers: M1 and M2. In other embodiments, the first metal interconnect layers 138a may include additional layers to facilitate additional or more precise signal control between the CMOS substrate 110 and other components of the semiconductor structure 100.

Above the first metal interconnect layers 138a, the semiconductor structure 100 includes first NAND cells 130a, 132a. The first NAND cells 130a, 132a may include memory cells 134 that are formed using alternating sacrificial word line and bit line layers separated by a dielectric. The term “sacrificial” as used herein refers to a structure, e.g., such as a layer in the stack, placed early in the process as a placeholder that is later removed and replaced with another layer/material in the final NOR device. For instance, the sacrificial word line and bit line layers serve as placeholders for the word lines and bit lines in the stack. The sacrificial word line and bit line layers will be selectively removed and replaced with conductive word line and bit line materials.

Suitable materials for sacrificial word line layer include, but are not limited to, materials such as amorphous carbon, silicon nitride (SiN), silicon oxynitride (SiON) and/or silicon oxycarbonitride (SiOCN). A process such as chemical vapor deposition (CVD), atomic layer deposition (ALD) or physical vapor deposition (PVD) can be used to deposit sacrificial word line layer on insulator line. According to an exemplary embodiment, sacrificial word line layer has a thickness of from about 5 nanometers (nm) to about 50 nm and ranges therebetween. Suitable materials for dielectric layer include, but are not limited to, oxide dielectric materials such as SiOx and/or silicon oxycarbide (SiOC). A process such as CVD, ALD or PVD can be used to deposit dielectric layer onto sacrificial word line layer. According to an exemplary embodiment, dielectric layer has a thickness of from about 5 nm to about 20 nm and ranges therebetween.

The materials employed for the successive iterations of sacrificial word line layers, dielectric layers, and sacrificial bit line layers provide etch selectivity at respective points in the process. For instance, during formation of the memory cells 134, an etch of the sacrificial word line layers selective to the dielectric layers and the sacrificial word line layers are used to form divots alongside channels in which the memory cells 134 will be formed. Similarly, the sacrificial bit line layers will be removed from the stack selective to the dielectric layers and replaced with the bit lines of the memory cells 134. The exemplary materials provided above for the sacrificial word line layers, dielectric layers, and sacrificial bit line layers advantageously provide the needed etch selectivity.

Each sacrificial word line layer in the first NAND cells 130, 132 is separated from the next adjacent sacrificial bit line layer by a dielectric layer. That is, a dielectric layer is deposited onto sacrificial bit line layer. As above, suitable materials for dielectric layer include, but are not limited to, oxide dielectric materials such as SiOx and/or SiOC deposited using a process such as CVD, ALD or PVD. According to an exemplary embodiment, dielectric layer has a thickness of from about 5 nm to about 20 nm and ranges therebetween.

After the first NAND cells 130a, 132a are fabricated, first vias 140a are patterned in the semiconductor structure 100. The first vias 140a are present at approximately the center between the first NAND cells 130a, 132a. Standard lithography and etching techniques can be used to pattern the first vias 140a through the first NAND cells 130a, 132a. With standard lithography and etching processes, a lithographic stack (e.g., photoresist/organic planarizing layer (OPL)/anti-reflective coating (ARC)), is used to pattern a hardmask (not shown). The pattern from the hardmask is then transferred to the underlying substrate (in this case the first NAND cells 130a, 132a). The hardmask is then removed. A directional (e.g., anisotropic) etching process such as reactive ion etching (RIE) can be employed for the first vias 140a. The first vias 140a are then finished with a metallization step.

For instance, the first vias 140a may be etched and then filled with a contact metal(s). Suitable contact metals include, but are not limited to, Cu, W, Ru, Co, Ni and/or Pt. The contact metal(s) can be deposited into the features using a process such as evaporation, sputtering or electrochemical plating. Prior to depositing the contact metal(s), a barrier layer (not shown) can be deposited into and lining the features to prevent diffusion of the contact metal(s) into the surrounding dielectric. As provided above, suitable barrier layer materials include, but are not limited to, Ru, Ta, TaN, Ti, and/or TiN. Additionally, a seed layer (not shown) can be deposited into and lining the features prior to contact metal deposition to facilitate plating of the contact metal(s).

After the first vias 140a are finished, first additional metal interconnect layers 150a, 160a are formed above the first NAND cells 130a, 132a. The first additional metal interconnect layers 150a, 160a may be formed similarly to the first metal interconnect layers 138a. That is, the first additional metal interconnect layers 150a, 160a include metal lines, trenches, and/or vias that interconnect to enable control of the FETs 118a, b in the CMOS substrate 110 and the memory cells 134 in the NAND cells 130a, 132a. According to an exemplary embodiment, the first additional metal interconnect layers 150a, 160a are formed from metal or other conductive material insulated by dielectric or other insulative material. In the illustrated embodiment, the first additional metal interconnect layers 150a, 160a include two metal interconnect layers: M3 and M4. In other embodiments, the first metal interconnect layers 138a may include additional layers to facilitate additional or more precise signal control between the CMOS substrate 110 and other components of the semiconductor structure 100.

The bottom first additional metal interconnect layer 150a may be designated as the first bitline 150a. In the illustrated embodiment, the first vertical NAND cell 130a, 132a is between the first bitline 150a and the CMOS substrate 110. The distance between the first bitline 150a and the CMOS substrate 110 can have a dramatic effect on the performance of the 3D stack NAND device, and therefore the number of memory cells 134 in the NAND cells 130a, 132a must be selected carefully: too many layers of memory cells 134 can mean that the first bitline 150a is too far from the CMOS substrate 110; while too few layers of memory cells 134 can mean that the cell density is not maximized. As described above, having NAND cells on both sides of the CMOS substrate 110 doubles the amount of memory cells 134 that can fit within a given distance between the CMOS substrate and the bitline 150a.

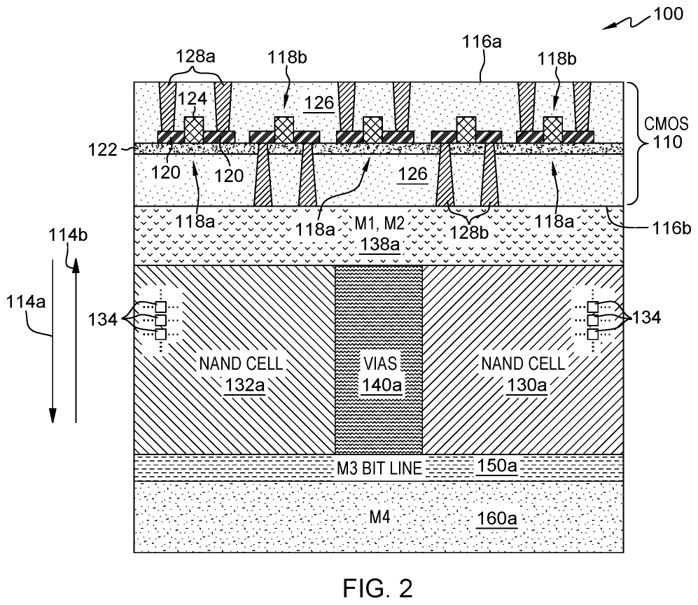

To fabricate the second half 112b of the semiconductor structure 100, the first half 112a (as completed through the steps shown in FIG. 1) is flipped. FIG. 2 depicts a schematic cross-sectional side view of the semiconductor structure 100 of FIG. 1 at a fabrication stage, in accordance with one embodiment of the present invention. The view of FIG. 2 shows the semiconductor structure 100 flipped relative to the view shown in FIG. 1. In the flipped state, the CMOS substrate 110 is located at the top. The first metal interconnect layers 138a are below the CMOS substrate 110, with the first NAND cells 130a, 132a and the first vias 140a below the first metal interconnect layers 138a. The first additional metal interconnect layers (including the bitline 150a, and the M4 layer 160a) are below the first NAND cells 130a, 132a and the first vias 140a. The second contacts 128b are now exposed at the top of the CMOS substrate 110, and are ready for a second half 112b of the semiconductor structure 100.

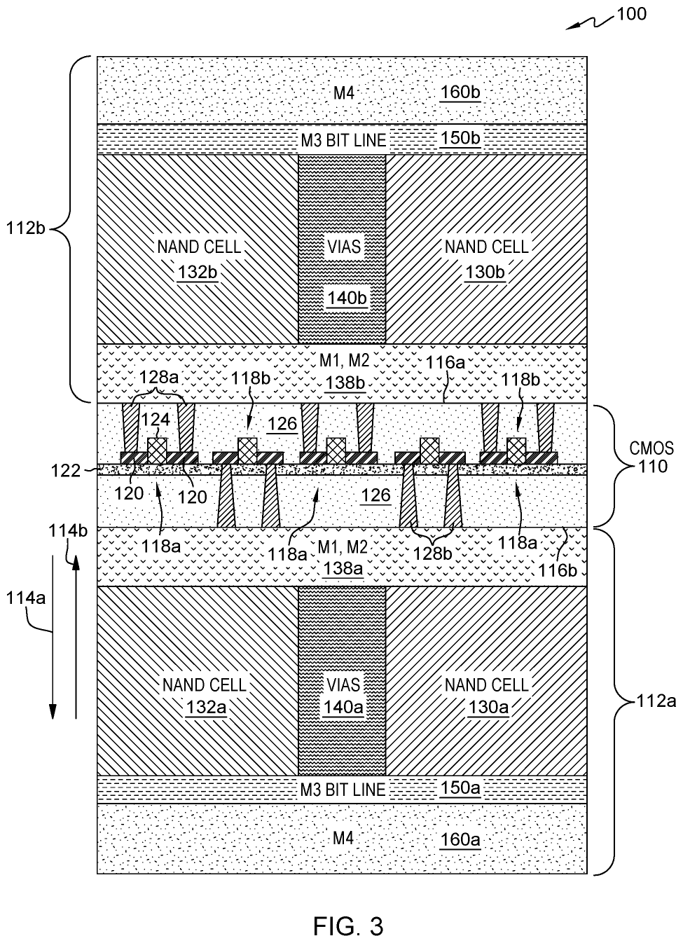

FIG. 3 is a cross-sectional side view of the semiconductor structure 100 of FIG. 1 at a fabrication stage, in accordance with one embodiment of the present invention. The semiconductor structure 100 includes a second half 112b with second metal interconnect layers 138b, second NAND cells 130b, 132b, second vias 140b, and second additional metal interconnect layers 150b, 160b. The second half 112b may be fabricated using similar methods to the first half 112a described above. For example, the second metal interconnect layers 138b may be formed on/above the CMOS substrate 110, with metallized lines, trenches, and/or vias that interconnect to enable control of the second FETs 118b in the CMOS substrate 110. The second metal interconnect layers 138b are connected only to the second FETs 118b (i.e., through the second contacts 128b) on the second side 116b of the CMOS substrate 110. In the illustrated embodiment, the second metal interconnect layers 138b include two metal interconnect layers: M1 and M2. In other embodiments, the second metal interconnect layers 138b may include additional layers to facilitate additional or more precise signal control between the CMOS substrate 110 and other components of the semiconductor structure 100.

Above the second metal interconnect layers 138b, the semiconductor structure 100 includes second NAND cells 130b, 132b. The second NAND cells 130b, 132b may include more memory cells 134 formed using the sacrificial word line and bit line layers described above. Second vias 140b may then be formed by etching through the second NAND cells 130b, 132b and metallizing the resulting holes.

Above the second NAND cells 130b, 132b and the second vias 140b, the semiconductor structure 100 includes second additional metal interconnect layers 150b, 160b. The second additional metal interconnect layers may include a second bitline 150b that designates the address each memory cell 134 in the second NAND cells 130b, 132b.

The illustrated embodiment in FIG. 3 shows double instances of metal interconnect layers (i.e., first metal interconnect layers 138a first additional metal interconnect layers 150a, 160a, second metal interconnect layers 138b, and second additional metal interconnect layers 150b, 160b), which requires double the space within the semiconductor structure 100. The space taken up by the metal interconnect layers, however, is minimal compared to the performance improvement gained due to the proximity of the bitlines 150a, 150b to the CMOS substrate 110.

The integrated circuit chips resulting from the processes described herein can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

While the present application has been particularly shown and described with respect to preferred embodiments thereof, it will be understood by those skilled in the art that the foregoing and other changes in forms and details may be made without departing from the spirit and scope of the present application. It is therefore intended that the present application is not limited to the exact forms and details described and illustrated, but fall within the scope of the appended claims.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a peripheral complimentary metal-oxide semiconductor (CMOS) substrate;
a first vertical NAND cell on a first side of the CMOS substrate; and
a second vertical NAND cell on a second side of the CMOS substrate opposite the first side.

2. The semiconductor structure of claim 1, wherein the CMOS substrate comprises:
a first CMOS device connected to the first vertical NAND cell; and
a second CMOS device connected to the second vertical NAND cell.

3. The semiconductor structure of claim 2, wherein the first CMOS device is insulated from the second CMOS device.

4. The semiconductor structure of claim 1, further comprising:
a first bitline, wherein the first vertical NAND cell is between the first bitline and the CMOS substrate; and
a second bitline, wherein the second vertical NAND cell is between the second bitline and the CMOS substrate.

5. The semiconductor structure of claim 4, further comprising:
a first via between the first bitline and the CMOS substrate; and
a second via between the second bitline and the CMOS substrate.

6. The semiconductor structure of claim 5, wherein the first via is formed in a center of the first vertical NAND cell.

7. The semiconductor structure of claim 1, wherein the CMOS substrate comprises:
a first field-effect transistor (FET) fabricated in a first orientation comprising a source/drain contact in a first direction; and
a second FET fabricated in the first orientation comprising a source/drain contact in a second direction opposite the first direction.

8. The semiconductor structure of claim 1, further comprising:
two first metal interconnect layers between the CMOS substrate and the first vertical NAND cell; and
two second metal interconnect layers between the CMOS substrate and the second vertical NAND cell.

9. The semiconductor structure of claim 8, further comprising:
two first additional metal interconnect layers, wherein the first vertical NAND cell is between the two first metal interconnect layers and the two first additional metal interconnect layers; and
two second additional metal interconnect layers, wherein the second vertical NAND cell is between the two second metal interconnect layers and the two second additional metal interconnect layers.

10. A method, comprising:
forming a peripheral complimentary metal-oxide semiconductor (CMOS) substrate;
forming a first vertical NAND cell on a first side of the CMOS substrate;
flipping the CMOS; and
forming a second vertical NAND cell on a second side of the CMOS substrate opposite the first side.

11. The method of claim 10, wherein forming the CMOS substrate comprises:
forming a first CMOS device comprising a contact on the first side of the CMOS substrate; and
forming a second CMOS device comprising a contact on the second side of the CMOS substrate.

12. The method of claim 11, wherein the first CMOS device is insulated from the second CMOS device.

13. The method of claim 10, further comprising:
forming a first bitline above the first vertical NAND cell; and
forming a second bitline above the second vertical NAND cell.

14. The method of claim 13, further comprising forming a first via between the first bitline and the CMOS substrate.

15. A semiconductor structure, comprising:
a first vertical NAND cell oriented in a first direction relative to a peripheral complimentary metal-oxide semiconductor (CMOS) substrate; and
a second vertical NAND cell oriented in a second direction opposite the first direction relative to the CMOS substrate.

16. The semiconductor structure of claim 15, further comprising:
a first bitline, wherein the first vertical NAND cell is between the first bitline and the CMOS substrate; and
a second bitline, wherein the second vertical NAND cell is between the second bitline and the CMOS substrate.

17. The semiconductor structure of claim 16, further comprising:
a first via between the first bitline and the CMOS substrate; and
a second via between the second bitline and the CMOS substrate.

18. The semiconductor structure of claim 15, wherein the CMOS substrate comprises:
a first field-effect transistor (FET) fabricated in a first orientation comprising a source/drain contact in the first direction; and
a second FET fabricated in the first orientation comprising a source/drain contact in the second direction.

19. The semiconductor structure of claim 15, further comprising:
two first metal interconnect layers between the CMOS substrate and the first vertical NAND cell; and
two second metal interconnect layers between the CMOS substrate and the second vertical NAND cell.

20. The semiconductor structure of claim 19, further comprising:
two first additional metal interconnect layers, wherein the first vertical NAND cell is between the two first metal interconnect layers and the two first additional metal interconnect layers; and
two second additional metal interconnect layers, wherein the second vertical NAND cell is between the two second metal interconnect layers and the two second additional metal interconnect layers.
